(19) United States
(12) Patent Application Publication
(10) Pub. No.: US 2007/0035933 A1
(43) Pub. Date: Feb. 15, 2007

(54) Blade interface device

(75) Inventor: Chih-Peng Chuang, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/395,835

(22) Filed: Mar. 30, 2006

(30) Foreign Application Priority Data
Aug. 9, 2005 (TW) 094213561

(51) Int. Cl. H05K 7/14

(52) U.S. Cl. 361/752; 361/796; 361/759; 361/801

(57) ABSTRACT

A blade interface device is provided, including a blade casing, a transfer card disposed to one inner side of the blade casing and having a first connector, an interface module having a second connector for longitudinally connecting with the first connector and a first fastening section, a positioning section disposed inside the blade casing for transversely position the interface module, and a second fastening section for longitudinally fastening the first fastening section of the interface module. Such a blade interface device could be directly installed inside a blade server.

### FIELD OF THE INVENTION

The present invention relates to an interface device and more particularly relates to a blade interface device that could be applied to a blade server.

### BACKGROUND OF THE INVENTION

With rapid innovations and developments of technologies, current enterprises often need to process a large amount of information. Particularly, with the development of globalized economy, to build a powerful network for long distance communication has become the focus of enterprises. Accordingly, how to use servers in such a network environment, which could effectively and securely collect and manage information and could also meet demands for high bandwidth, optimal system performance, high extensibility and low maintenance cost, has become more and more important.

Conventionally, multiple servers are disposed in a cabinet and each server has its own power cable, Ethernet interface, system manage, power supply, keyboard/monitor/mouse interface and fiber exchange interface etc. As a result, hundreds of cables need to be disposed in the cabinet, which not only takes up a lot of space, but also makes it difficult to identify a fault unit in the event of error occurrence. Moreover, it is not so convenient to install or replace a server. To resolve these aforementioned disadvantages, blade servers are proposed.

The main difference of a blade server from a conventional pedestal server or a rackmount server is that each independent server becomes a “fasciate” blade casing that highly integrates a CPU (Central Processor Unit), a hard disk driver, a memory, a network interface and a control chip. Further, a plurality of such blade casings is inserted side by side to a backplane of the blade server, these blade casings sharing a power supply, a fan, a mouse, a keyboard and a monitor interface device. Compared with a conventional pedestal server or rackmount server, a blade server becomes much smaller in size, needs fewer cables and is much easier to manage.

However, such a blade server has some application barriers. For example, some enterprises need to insert an interface module such as a PCI (Peripheral Component Interconnect) card to a server for process management. However, it is impossible for a normal blade casing to hold the interface module. One possible way is to insert the PCI card directly to a motherboard. Unfortunately, a lot of space of the motherboard is taken up, thereby affecting optimal arrangement of the components on the motherboard and decreasing the number of components that can be disposed on the motherboard. Consequently, the specification of blade casings need to be varied, thereby affecting the function extensibility of blade servers.

### SUMMARY OF THE INVENTION

To overcome the above-mentioned problems of the prior art, the primary objective of the present invention is to provide a blade interface device to increase function extensibility of blade servers.

Another objective of the present invention is to provide a blade interface device which could be easily installed.

To achieve the above and other objectives, the present invention provides a blade interface device, including: a blade casing, a transfer card disposed to one inner side of the blade casing and having a first connector; an interface module having a second connector for longitudinally connecting with the first connector and a first fastening section, a positioning section disposed inside the blade casing for transversely position the interface module, and a second fastening section for longitudinally fastening the first fastening section of the interface module

Preferably, the transfer card could be a circuit board, which could further include a third connector for electrically connecting with other components. In a preferred embodiment, the interface module could be a PCI (Peripheral Component Interconnect) card, which is not limited thereto. The first fastening section could be a sheet or the like. A screw hole could be formed on the first fastening section. The interface module further includes a lock section such that the interface module could be locked to the blade casing by a lock component such as a screw. The positioning section could be disposed perpendicularly to bottom of the blade casing. The positioning section could include a notch. The second fastening section has a lock hole.

In a preferred embodiment, the blade interface device further includes a first latch section and/or a second latch section for latching front of the first fastening section, thereby enhancing positioning effect of the interface module. Preferably, the first latch section transversely protrudes from the transfer card. The second latch section could be disposed to bottom of the blade casing, which could be a slot or the like.

Compared with the prior art, the present invention provides a blade interface device by integrating the interface module to a blade casing of blade servers without the need of inserting an interface module such as a PCI card to a motherboard, thereby saving space of the motherboard and increasing function extensibility of blade servers.

Meanwhile, because the blade interface device of the present invention could be longitudinally and transversely positioned and only one single screw component is needed to lock the interface module to the blade casing, the blade interface device could be easily and quickly installed.

Other aspects and features will become apparent to those ordinarily skilled in the art upon review of the following description of the preferred embodiments of the present invention in conjunction with the accompanying drawings.

### DESCRIPTION OF THE PREFERRED EMBODIMENTS

The present invention relates to a blade interface device to be applied to a blade server. In the following preferred embodiment, a blade interface device having an interface module such as a PCI (Peripheral Component Interconnect) card disposed in a blade casing is described. However, one of ordinary skill in the art will readily recognize that other interface modules could be included in the blade interface device. Moreover, for purpose of simplification, the drawings only show structures related to the present invention.

Referring to FIGS. 1 and 2, a blade interface device 100 according to the present embodiment includes a blade casing 1, a transfer card 3 disposed to one inner side of the blade casing I and having a first connector 31, an interface module 5 having a second connector 51 for longitudinally connecting with the first connector 31 and a first fastening section 53, a positioning section 7 disposed inside the blade casing 1 to transversely position the interface module 5, and a second fastening section 9 disposed inside the blade casing 1 for longitudinally fastening to the corresponding first fastening section 53 (as shown in FIG. 2).

As shown in FIG. 1, the blade casing 1 may be one of a plurality of casings of a blade server (not shown). Different from other casings of the blade server, the blade casing 1 contains an interface module 5 such as a PCI card instead of a hard disk drive.

The transfer card 3 could be a circuit board. Besides the first connector 31 longitudinally connected with the second connector 51, the transfer card 3 further includes a third connector 33 for electrically connecting with the back plane (not shown), which will be described later.

Similar to prior art interface modules, the interface module 5 has four corners formed respectively a horizontally protruding lock section 55 which has lower elevation than the surface of the interface module 5. The difference of the interface module 5 from the prior art interface modules is that to one side of the interface module 5 there disposed the first fastening section 53 which could be a sheet and further include a screw hole 531, function of which will be described later.

The positioning section 7 could be disposed perpendicularly to the blade casing 1 and integrally formed with the blade casing 1. Alternatively, the positioning section 7 and the blade casing 1 could be formed separately and assembled together afterwards. In the present embodiment, the positioning section 7 has a notch 71 which could fasten the lock section 55 of the interface module 5 to transversely position the interface module 5.

As shown in FIG. 2, the second fastening section 9 extending backward from the front of the blade casing 1 could be integrally formed with the blade casing 1 or formed separately. In the present embodiment, the second fastening section 9 has a lock hole 91 such that the first fastening section 53 could be fastened to the second fastening section 9 through a lock component 10 that passes through the screw hole 531 and the lock hole 91, thereby longitudinally fastening the interface module 5 to the blade casing 1.

In another preferred embodiment, as shown in FIG. 2, the blade interface device 100 further includes a first latch section 35 and/or a second latch section 11. The first latch section 35 protrudes horizontally from the transfer card 3 for latching front of the first fastening section 53. The second latch section 11 could be a slot formed at bottom of the blade casing 1. The front of the first fastening section 53 in a concave shape could be changed to a hook structure such that the second latch section 11 could latch the front of the first fastening section 53.

To assemble the blade interface device 100 according to the present embodiment, first, push the interface module 5 into the blade casing 1, and then longitudinally connect the second connector 51 with the first connector 31 and coupling the notch 71 of the positioning section 7 with the lock section 55 of the interface module 5, thereby determining position of the interface module 5 inside the blade casing 1.

In another embodiment, the positioning effect could be enhanced by latching the first latch section 35 and/or the second latch section 11 with the first fastening section 53.

Next, let the lock component 10 pass through the screw hole 531 and the lock hole 91 to longitudinally fasten the first fastening section 53, thereby secularly holding the interface module 5 in the blade casing 1, as shown in FIG. 3.

FIG. 4 shows a blade server including two blade interface devices 100 according to the present embodiment and a blade system 200. Inside blade casings of the blade system 200, hard disk drivers could be disposed. As shown in FIG. 4, one of the blade interface devices 100 is connected to a back plane 201 through a third connector 33. As shown in FIG. 5, function extensibility of the blade server is increased by integrating the blade interface devices 100 with the blade system 200.

However, one of ordinary skill in the art will readily recognize that the number and position of the blade interface devices 100 and the blade system 200 could be changed. Accordingly, the present embodiment is only exemplary and will not limit the present invention.

Compared with the prior art, the blade interface device of the present invention could be disposed in a blade server without the need of changing specification of the casing, thereby saving space of the motherboard, increasing flexibility of the motherboard arrangement and increasing function extensibility of the blade server.

Moreover, the interface module could be easily and conveniently installed to the blade casing 1 by only one screw, which is much easy and convenient.

In addition, the present invention not only could use the conventional interface modules and blade casings, but also could design new interface modules and blade casings, thereby increasing design flexibility.

Although the present invention has been described in accordance with the embodiments shown, it would be appreciated by those skilled in the art that changes may be made in these embodiments without departing from the principles and sprit of the present invention.

### BRIEF DESCRIPTION OF THE DRAWINGS

FIG. 1 is an exploded view of a blade interface device according to a preferred embodiment of the present invention;

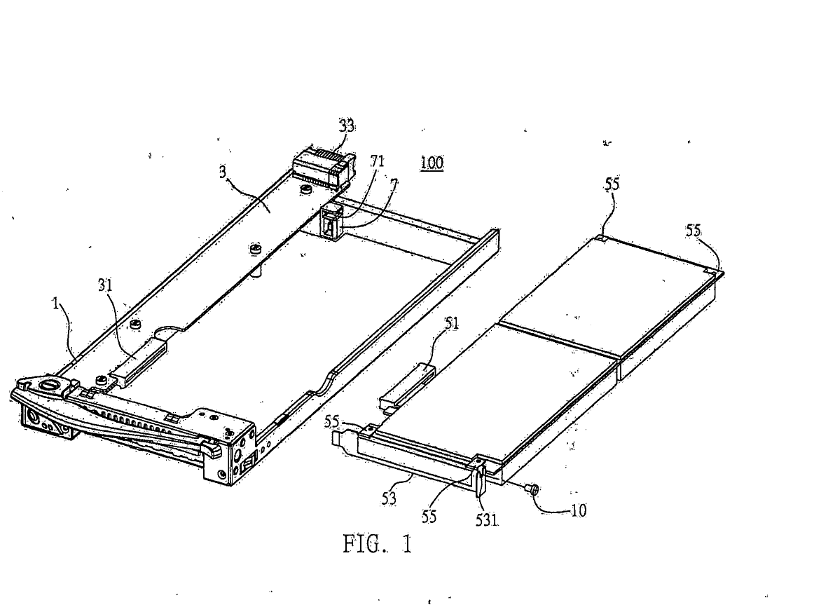

FIG. 2 is a block diagram of blade casing of the blade interface device in FIG. 1;

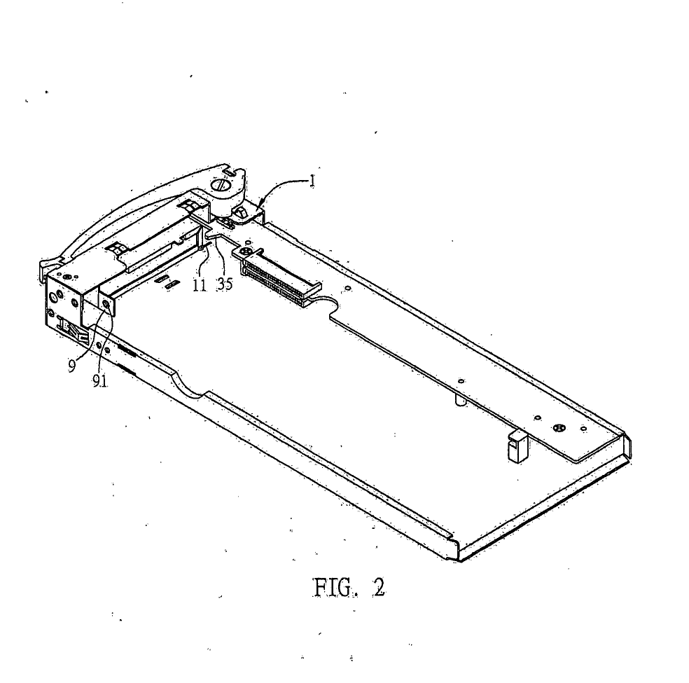

FIG. 3 is a diagram showing an assembled structure of the blade interface device in FIG. 1;

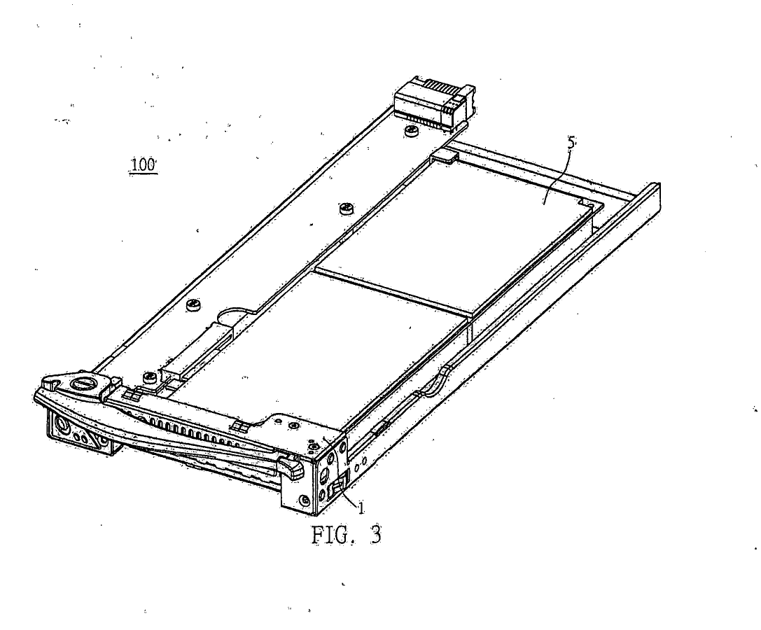

FIG. 4 is a diagram showing structure of a blade sever including the blade interface device in FIG. 3; and

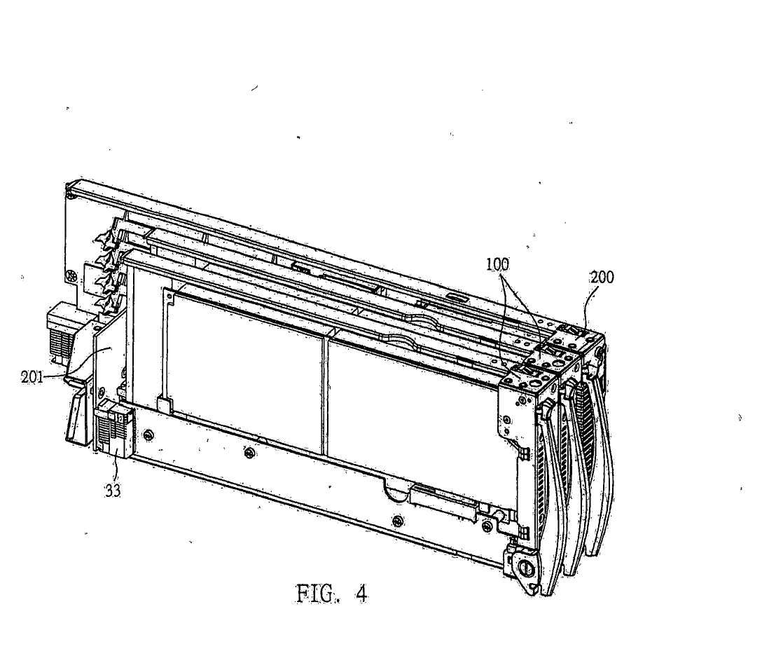

FIG. 5 is a side view of the blade server in FIG. 4.

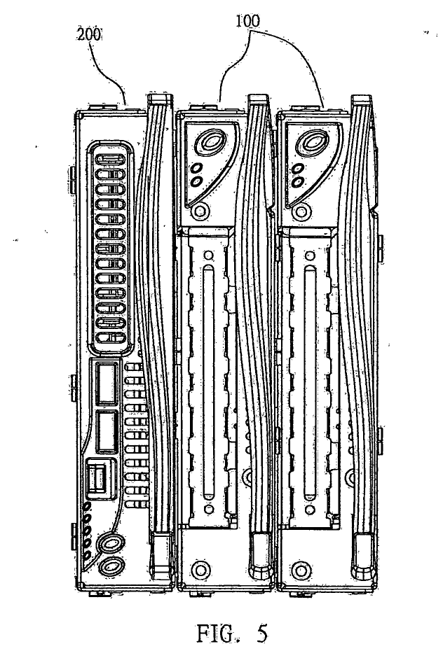

What is claimed is:

1. A blade interface device, comprising:
a blade casing;
a transfer card disposed to one inner side of the blade casing and having a first connector;
an interface module having a second connector for longitudinally connecting with the first connector and a first fastening section;
a positioning section disposed inside the blade casing to transversely position the interface module; and
a second fastening section disposed inside the blade casing for longitudinally fastening the first fastening section.

2. The blade interface device of claim 1, wherein the transfer card is a circuit board.

3. The blade interface device of claim 1, wherein the transfer card further includes a third connector.

4. The blade interface device of claim 1, wherein the interface module is a PCI (Peripheral Component Interconnect) card.

5. The blade interface device of claim 1, wherein the first fastening section is a sheet.

6. The blade interface device of claim 1, wherein the first fastening section includes a screw hole.

7. The blade interface device of claim 1, wherein the interface module further includes a lock section.

8. The blade interface device of claim 1, wherein the positioning section is disposed perpendicularly to bottom of the blade casing.

9. The blade interface device of claim 1, wherein the positioning section has a notch.

10. The blade interface device of claim 1, wherein the second fastening section includes a lock hole.

11. The blade interface device of claim 1 further includes a first latch section.

12. The blade interface device of claim 11, wherein the first latch section transversely protrudes from the transfer card.

13. The blade interface device of claim 1 further includes a second latch section.

14. The blade interface device of claim 13, wherein the second latch section is disposed to bottom of the blade casing.

15. The blade interface device of claim 13, wherein the second latch section is a slot.
